(19) United States
(12) Patent Application Publication
(10) Pub. No.: US 2001/0043072 A1
(43) Pub. Date: Nov. 22, 2001

(54) Programmable electronic flasher relays

(76) Inventor: Andreas Fritz, Brackenheim (DE)

Correspondence Address: FASSE PATENT ATTORNEYS, P.A., P.O. BOX 726, HAMPDEN, ME, 04444-0726, US

(21) Appl. No.: 09/837,254

(22) Filed: Apr. 18, 2001

(30) Foreign Application Priority Data
May 16, 2000 (DE) 100 24 042.9

(51) Int. Cl. G01R 31/02; G01R 31/327

(52) U.S. Cl. 324/418

(57) ABSTRACT

Method for monitoring a load circuit with an electronic flasher relay. In known methods, the comparison threshold is obtained from a voltage measurement made during operation and stored in a volatile memory in order to record a load element failure. If the load elements malfunction during voltage measurement, incorrect comparison thresholds are defined. In accordance with the method according to the invention, the characteristic values for determining the voltage thresholds are stored in a non-volatile memory before the load circuit commences operation. Thus, no malfunction can occur as a result of incorrectly defined comparison thresholds.

### BACKGROUND

1. Field of the Invention

The present invention relates to a method for monitoring a load circuit of a flasher relay in accordance with the preamble of Patent claim 1.

2. Description of the Related Technology

Publication EP 0 870 646 A2 describes a method of this kind in which the failure of one or several flashing lamps is detected by means of a single measuring resistor. In order to record a malfunction of the load circuit, the current flowing through the flashing lamps is fed over the measuring resistor and the generated voltage drop is compared with a predetermined voltage threshold. This voltage threshold is obtained while the battery voltage is applied by measuring, after switching on the ignition, the voltage across the measuring resistor when a direction flasher is operated for the first time and storing it as reference value in a volatile memory. Another precondition is that a direction flasher is operated at least twice. A voltage threshold is generated which depends on the battery voltage and the current flowing through the measuring resistor. This is stored in a volatile memory.

An important area of application for electronic flasher relays is in motor vehicles. In accordance with the motor vehicle registration requirements, failure of a flashing lamp must be detected by the flasher relay and be indicated to the vehicle driver in either optical or acoustic form. This is done by the flasher relay doubling the flash frequency and informing the driver optically by means of an indicator lamp on the dashboard or acoustically through the increased frequency of the flash relay. Since the flashing lamps in Europe have a power of 21 watts, whereas in the U.S.A. also main lamps with powers of 27 watts and more are fitted and, in addition, a different number of flashing lamps is used depending on the model, a number of combinations result with respect to the power to be monitored. The requirement calls for a single flasher relay to be made with a minimum number of external components for all variants.

A disadvantage of the method described in EP 0 870 646 A2 is that after each power supply failure, caused for instance by disconnecting the battery, the voltage threshold values are deleted. The voltage thresholds can, however, be reset only when the ignition is switched on and can be effected only by operating a direction flasher at least twice. Only then can the circuit again detect any malfunction such as, for example, the failure of flashing lamps. However, if a flashing lamp is defective while defining the voltage threshold, or if direction flashing is not performed properly, the circuit determines the values of the voltage thresholds incorrectly. This can lead to a continuous malfunction of the flasher relay until a new reset is performed. If flashing lamps fail in this time, it will either not be detected or it will be identified incorrectly. Another disadvantage is that the flasher relay needs current even in the non-operated state in order to retain the values of the voltage thresholds in the memories.

### SUMMARY OF THE INVENTION

The object of the present invention is to specify a method with which the internal voltage thresholds can be defined and changed if necessary without having to operate the flasher relay in the motor vehicle and with which the values of the voltage thresholds are retained even when the supply voltage (battery voltage) is disconnected. Another object is to specify a circuit arrangement for performing the method that can be manufactured easily and at low cost.

The first-mentioned object is solved by the characterizing features of Patent claim 1. Favorable variants are the object of Subclaims.

Accordingly, the essence of the invention is that for monitoring a load circuit in an electronic flasher relay one or several characteristic values that are used as voltage thresholds are stored in a non-volatile memory, preferably before applying a supply voltage. The characteristic values are determined from the total power of the load elements for a given supply voltage. When the load circuit is operated, the voltage thresholds are then compared with the voltage value at the measuring resistor. Both the voltage thresholds and the voltage value measured at the measuring resistor are increased or decreased by the same amount in accordance with the operating voltage. The result of the comparison is thus independent of the supply voltage. Since storage of the values takes place in a non-volatile memory, these values are retained even after disconnecting the supply voltage. This is particularly advantageous when using the circuit as flasher relay in the motor vehicle because in the event of repairs, for example when replacing the battery, the circuit is isolated completely from the supply voltage. The possibilities resulting from incorrect programming therefore do not apply. Furthermore, the method according to the invention requires no bias current and therefore the battery is not subjected to loading when the ignition is switched off.

### BRIEF DESCRIPTION OF THE FIGURE

The invention will now be described and explained with reference to the drawing in FIG. 1:

FIG. 1 Block diagram to explain the method according to the invention.

### DESCRIPTION OF THE PREFERRED EMBODIMENTS

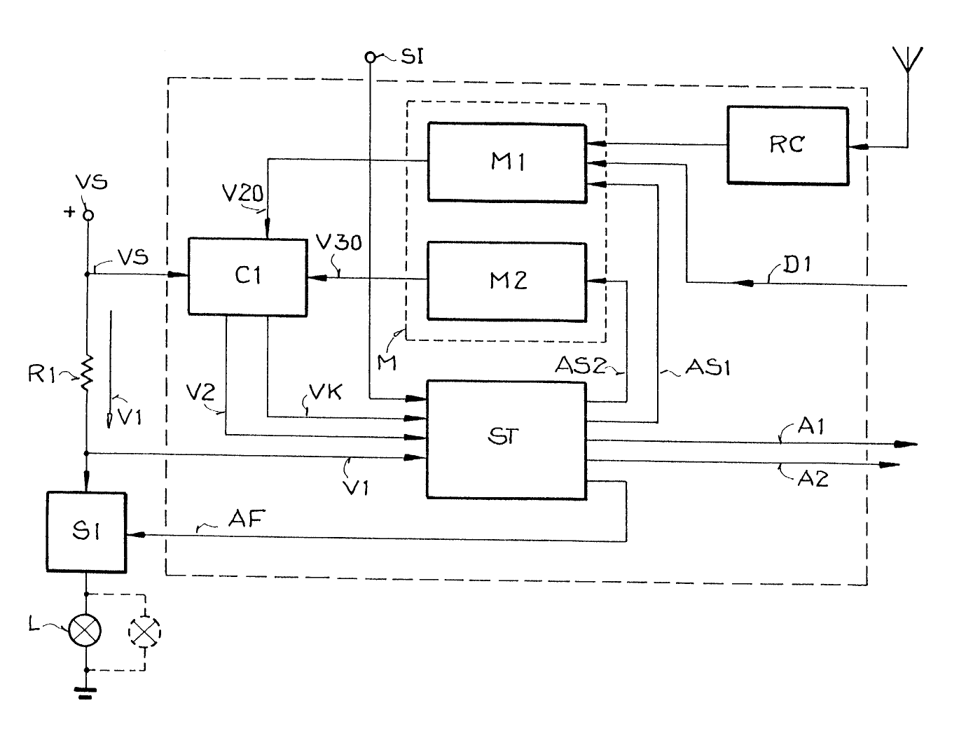

The memory unit M shown in FIG. 1 consists of a non-volatile memory M1 and a volatile memory M2. The non-volatile memory is preferably programmed before starting up the circuit arrangement with the characteristic values V20 (normal operation), VK0 (short-circuit incident) for the calculation of the voltage thresholds V2, VK. The voltage thresholds V2, VK are calculated in the check unit C1, for instance by means of comparators, in that the values V20, VK0 are increased or decreased depending on the level of the applied supply voltage VS. The value V20 results from the number of load elements L (flashing lamps), their power and the magnitude of a measuring resistor R1. During operation, the voltage threshold V2 is used correspondingly to detect a malfunction in the load circuit. The second voltage threshold VK is used to detect a short-circuit in the load circuit. Both voltage thresholds V2, VK are applied by the check unit C1 to the inputs of the control unit ST. When the load circuit is in operation, the switching unit S1 is driven by the control unit ST with a signal that varies with time. The voltage value V1, the level of which is proportional to the current in the load circuit, is also applied to an input of the control unit ST. With each switching operation of the switching unit S1, this compares the value V1 with the two voltage thresholds V2, VK. For the result of the comparison, there are four different cases:

Case 1: The measured voltage value V1 corresponds to the value of the voltage threshold V2. The control unit S1 is driven with the normal frequency from the control unit ST. The outputs A1, A2 are not active.

Case 2: If the measured voltage value V1 is below the voltage threshold V2, a failure of the load elements L at the output of the control unit ST is indicated in that the clock frequency of the switching unit S1 is increased and a further output signal A1 is output for driving indicator lamps.

Case 3: If the maximum voltage value V1 measured at the resistor R1 equals the voltage threshold VK, a short-circuit is indicated by the control unit ST at the output A2 and the load circuit current is temporarily switched off.

Case 4: If the measured voltage value V1 is within the interval given by the voltage thresholds V2, VK, the control unit ST recognizes that additional load elements L have been connected, for instance by attaching a trailer to the motor vehicle. As a consequence, the control unit ST puts into memory unit M2 a new characteristic value V30 corresponding to the voltage value V1 measured at measuring resistor R1. This characteristic value V30 overwrites the previous voltage threshold V2 in the check unit C1, i.e. the lower voltage threshold that is relevant for comparison with the voltage value V1 is elevated. This state is retained until the signal voltage S1 is switched off, for example by switching off the ignition. After switching on again, the characteristic value V20 originally stored in the non-volatile memory is then used.

Not only reprogrammable memories can be used for the non-volatile memories, for instance EEPROMS, but also single programmable memories such as zap stages (blowing of zener diodes) or fuse stages (vaporizing of printed conductors). The characteristic values V20, VK0 for the voltage thresholds V2 and VK respectively can be transferred without contact by means of inductive or infrared data transmission via the receiver RC or by direct contacting, for instance by means of a serial interface via the signal line D1.

What is claimed is:

1. Method for monitoring a load circuit with an electronic flasher relay in which the entire load current is taken via a measuring resistor (R1) and in which the voltage drop (V1) which occurs across the measuring resistor (R1) is compared electronically by a control unit (ST), with a voltage threshold (V2) calculated by a check unit (C1) from a characteristic value (V20) according to the applied supply voltage (VS) and with an output signal (A1, A2, AS1, AS2) being generated as the result of the comparison by the control unit (ST)
wherein
the characteristic value (V20) which is determined from the total power of the load elements (L) used at a given supply voltage is stored in a nonvolatile memory (M1).

2. Method in accordance with claim 1, wherein the characteristic value (V20) is put into storage in the non-volatile memory (M1) before the load circuit commences operation.

3. Method in accordance with claim 1, wherein at a voltage value (V1) across the measuring resistor (R1) that is lower than the threshold value (V2) a failure of the load element (L) is indicated in that preferably the clock frequency (AF) of a switching unit (S1) is modified or an indicator lamp is driven by an output signal (A1).

4. Method in accordance with claim 2, wherein at a voltage value (V1) across the measuring resistor (R1) that is lower than the threshold value (V2) a failure of the load element (L) is indicated in that preferably the clock frequency (AF) of a switching unit (S1) is modified or an indicator lamp is driven by an output signal (A1).

5. Method in accordance with claim 4, wherein for the purpose of determining a short-circuit in the non-volatile memory (M1) an additional characteristic value (VK0) is put into storage in the non-volatile memory (M1) and from this an additional voltage threshold (VK) is calculated that is greater than the previous voltage threshold (V2) and, provided the measured voltage value (V1) corresponds to the voltage threshold (VK), an output signal (A2) is generated.

6. Method in accordance with claim 5, wherein when the voltage value (V1) is within the interval given by the voltage threshold (V2) and the voltage threshold (VK), a characteristic value (V30) which is between the characteristic values (V20, VK0) is put into storage in a volatile memory (M2) and thus a new voltage threshold (V2) is calculated by the check unit (C1).

7. Method in accordance with claim 5, wherein the characteristic values (V20, VK0) are put into storage in reprogrammable non-volatile memories (M1), for example an EEPROM.

8. Method in accordance with claim 5, wherein the characteristic values (V20, VK0) are put into storage in single programmable non-volatile memories (M1), for example by blowing a zener diode or vaporizing a printed conductor.

9. Method in accordance with claim 5, wherein the input of the characteristic values (V20, VK0) for the voltage thresholds (V2, VK) is effected without contact, for instance by means of inductive or infrared data transfer.

10. Circuit arrangement for performing the method in accordance with claims 1 to 8, with a measuring resistor (R1), at least one switching element (S1) for controlling the load circuit, at least one switched load element (L), for example flashing lamps, an integrated circuit with at least one check unit (C1) for forming the voltage thresholds (V2, VK) and a control unit (ST)
wherein
a memory unit (M) is integrated that can be programmed internally by the control unit (ST) or externally via a receiver unit (RC) or by applying signal levels (D1), and
the check unit (C1) reads out the non-volatile memory (M1) and the control unit (ST) makes the two voltage thresholds (V2, VK) available.
